(19) United States
(12) Patent Application Publication
(10) Pub. No.: US 2025/0062106 A1
(43) Pub. Date: Feb. 20, 2025

(54) REMOTE PLASMA CLEAN (RPC) DELIVERY INLET ADAPTER

(71) Applicant: Lam Research Corporation, Fremont, CA (US)

(72) Inventors: Danae Nicole Kay, Austin, TX (US); Thomas Mark Pratt, Los Gatos, CA (US); Matthew Palmer Kwan, Pleasanton, CA (US)

(21) Appl. No.: 18/719,822

(22) PCT Filed: Dec. 12, 2022
(86) PCT No.: PCT/US2022/052568

§ 371 Date: Jun. 13, 2024

Related U.S. Application Data
(60) Provisional application No. 63/290,893, filed on Dec. 17, 2021.

(51) Int. Cl. H01J 37/32; C23C 16/44

(52) U.S. Cl. CPC H01J 37/32862; C23C 16/4405; C23C 16/4408; H01J 37/32357; H01J 37/32449; H01J 2237/3321; H01J 2237/335

(57) ABSTRACT

A gas delivery apparatus includes an inlet portion and an outlet portion. The inlet portion can comprise a plurality of inlet ports configured to receive gas from a gas source. The inlet portion can also comprise a corresponding plurality of tapered surfaces associated with the plurality of inlet ports. Each tapered surface of the plurality of tapered surfaces surrounds a corresponding inlet port of the plurality of inlet ports. The outlet portion can be configured to deliver the gas to a gas showerhead of a process chamber. Each tapered surface of the plurality of tapered surfaces can comprise a first region and a second region. The first region is associated with a first curvature. The second region is associated with a second curvature. The first curvature can be different from the second curvature.

### CLAIM OF PRIORITY

This application is a U.S. National Stage Filing under 35 U.S.C. 371 from International Application No. PCT/US2022/052568, filed on Dec. 12, 2022, and published as WO 2023/114145 A1 on Jun. 2, 2023, which claims the benefit of priority to U.S. patent application Ser. No. 63/290,893, filed on Dec. 17, 2021, each of which is incorporated by reference herein in its entirety.

### TECHNICAL FIELD

The subject matter disclosed herein generally relates to systems, methods, apparatuses, and machine-readable media associated with remote plasma clean (RPC) functionalities for cleaning internal surfaces of process chambers from residue deposits.

### BACKGROUND

Semiconductor substrate processing apparatuses are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL) processing, and resist removal.

During semiconductor substrate processing, the presence of chemical reactants within the process chamber results in residue deposits on the internal surfaces of the chamber. For example, the process chamber may be covered with carbon residue deposits after amorphous hard mask (AHM) processing is applied to the substrate. With conventional chamber cleaning techniques, a substantial portion of the cleaning gases introduced within the process chamber, such as remote plasma source (RPS) activated cleaning gas radical species (e.g., atomic oxygen or fluorine), can react with chamber surfaces that do not have residue deposits. Reactions between chamber walls and cleaning gases, as well as incomplete etching of residue deposits, introduce particle excursions within the process chamber, which can extend up to the cleaning gas delivery pathway, resulting in an increased amount of adders accumulating on the substrate during processing in the chamber. As used herein, the term “adders” is associated with the difference in defect counts (e.g., particles) before and after a test wafer is run through a process chamber.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for RPC-related techniques. Such techniques include removing residue deposits from a process chamber using a gas delivery apparatus with tapered surfaces.

In an example embodiment, a gas delivery apparatus includes an inlet portion. The inlet portion includes a plurality of inlet ports configured to receive gas from a gas source. The inlet portion further includes a corresponding plurality of tapered surfaces associated with the plurality of inlet ports. Each tapered surface of the plurality of tapered surfaces surrounds a corresponding inlet port of the plurality of inlet ports. The gas delivery apparatus also includes an outlet portion. The outlet portion is configured to deliver the gas to a gas showerhead of a process chamber.

In another example embodiment, a method for removing residue deposits from a process chamber includes providing a gas delivery apparatus. The gas delivery apparatus includes an inlet portion and an outlet portion. The inlet portion includes a plurality of inlet ports. The inlet portion also includes a corresponding plurality of tapered surfaces associated with the plurality of inlet ports. Each tapered surface of the plurality of tapered surfaces surrounds a corresponding inlet port of the plurality of inlet ports. The method further includes coupling the outlet portion of the gas delivery apparatus to a showerhead of the process chamber. The method further includes coupling the inlet portion to a remote plasma source (RPS). The method further includes admitting cleaning gas generated by the RPS into the process chamber through the plurality of inlet ports of the gas delivery apparatus and the showerhead. The method further includes removing the residue deposits from the process chamber using the cleaning gas. In some aspects, the cleaning gas is run infrequently. The back-streaming of particles from the process chamber is also reduced by a constant flow of inert gas through the body of the RPS, across the swept surfaces, and into the showerhead.

In yet another example embodiment, a semiconductor substrate processing apparatus includes a remote plasma source (RPS) configured to generate a cleaning gas. The semiconductor substrate processing apparatus also includes a gas delivery apparatus coupled with the RPS. The gas delivery apparatus includes an inlet portion and an outlet portion. The inlet portion includes a plurality of inlet ports configured to receive gas from a gas source. The inlet portion also includes a corresponding plurality of tapered surfaces associated with the plurality of inlet ports. Each tapered surface of the plurality of tapered surfaces surrounds a corresponding inlet port of the plurality of inlet ports. The semiconductor substrate processing apparatus also includes a process chamber in which a semiconductor substrate is processed, and residue deposits are formed. The process chamber is fluidly coupled to the RPS via the inlet portion and the outlet portion. The semiconductor substrate processing apparatus also includes a controller module coupled to the RPS, the gas delivery apparatus, and the process chamber. The controller module causes the RPS to supply the cleaning gas into the process chamber via the inlet portion and the outlet portion.

### BRIEF DESCRIPTION OF THE DRAWINGS

Various ones of the appended drawings merely illustrate example embodiments of the present disclosure and cannot be considered as limiting its scope.

FIG. 1 is a functional block diagram of an example of a substrate processing system in which examples of the present disclosure may be used.

FIG. 2 illustrates an inlet portion of a first gas delivery apparatus such as an RPC tube, which can be used in connection with removing residue deposits from a process chamber.

FIG. 3 illustrates an inlet portion of a second gas delivery apparatus, according to example embodiments,

FIG. 4 illustrates a first cross-sectional view of the second gas delivery apparatus of FIG. 3, according to example embodiments.

FIG. 5 illustrates a second cross-sectional view of the second gas delivery apparatus of FIG. 3, according to example embodiments.

FIG. 6 illustrates a top view of the inlet portion of the second gas delivery apparatus of FIG. 3, including multiple sloped regions, according to example embodiments.

FIG. 7 illustrates a top view of a first region of the multiple sloped regions of FIG. 6, according to example embodiments,

FIG. 8 illustrates a side view of an example tool cutout for providing the first region of FIG. 7, according to example embodiments.

FIG. 9 illustrates a top view of an example tool cutout for providing the first region of FIG. 7, according to example embodiments,

FIG. 10 illustrates atop view of multiple tool cutouts for providing neighboring first regions associated with a hyperbolic profile, according to example embodiments.

FIG. 11 illustrates a cross-sectional view 1100 of neighboring tapered surfaces associated with hyperbolic profiles, according to example embodiments.

FIG. 12 illustrates a top view of a second region of the multiple sloped regions of FIG. 6, according to example embodiments.

FIG. 13 illustrates a top view of a first cut, which may be used for producing the second region of FIG. 12, according to example embodiments.

FIG. 14 illustrates a cross-sectional view of the first cut of FIG. 13, according to example embodiments.

FIG. 15 illustrates a top view of a last cut that may be used for producing the second region of FIG. 12, according to example embodiments.

FIG. 16 illustrates a cross-sectional view of the last cut of FIG. 15, according to example embodiments.

FIG. 17 illustrates atop view of the inlet portion of the second gas delivery apparatus of FIG. 3, including blended regions with a smooth profile between the multiple sloped regions, according to example embodiments.

FIG. 18 is a flowchart of a method for removing residue deposits from a process chamber using a delivery inlet adapter with profiled surfaces, according to an example embodiment.

FIG. 19 is a block diagram illustrating an example of a machine upon which one or more example method embodiments may be implemented or by which one or more example embodiments may be controlled.

### DETAILED DESCRIPTION

The description that follows includes systems, methods, techniques, instruction sequences, and computing machine program products (e.g., stored on machine-readable media) that embody illustrative embodiments of the present disclosure. In the following description, for purposes of explanation, numerous specific details are outlined to provide a thorough understanding of example embodiments directed to the intermittent stagnant flow of cleaning gases within a process chamber for purposes of removing residue deposits from surfaces of the process chamber. It will be evident, however, to one skilled in the art that the present embodiments may be practiced without these specific details.

In this application, the terms “semiconductor wafer,” “wafer,” “substrate,” “semiconductor substrate,” and “wafer substrate” are used interchangeably. The terms “chamber,” “reaction chamber,” “deposition chamber,” “reactor,” “chemical isolation chamber,” “process chamber,” “processing chamber,” and “substrate processing chamber” are also used interchangeably.

One type of substrate processing apparatus can include a process chamber containing top and bottom electrodes where radio frequency (RF) power is applied between the electrodes to excite a process gas into plasma for processing semiconductor substrates in the process chamber. Another type of substrate processing apparatus can include an ALD tool, which is a specialized type of CVD processing system in which ALD reactions occur between two or more chemical species introduced as process gasses within a process chamber (e.g., an ALD process chamber). A CVD processing system can be configured to operate without plasma, while a plasma-enhanced CVD (or PE-CVD) processing system is configured to operate with plasma. Similarly, an ALD processing system can be configured to operate with or without plasma. The process gasses (e.g. precursor gases) are used to form (e.g., during multiple ALD cycles) a thin film deposition of a material on a substrate, such as a silicon wafer, as used in the semiconductor industry. The precursor gases can be sequentially introduced into the ALD processing chamber from a gas source so that the gases react with a surface of the substrate to form a deposition layer upon combining. For example, the substrate is typically exposed to process gasses including a first chemical (or a combination of chemicals) to form an absorbed layer. The excess of the first chemical or chemicals can be removed by pumping or purging. The process gasses can include at least a second chemical or a combination of chemicals. The at least second chemical can be introduced to react with the absorbed layer to form a deposited material layer. The two chemicals or combinations of chemicals can be explicitly selected to react with one another to form the deposited material layer.

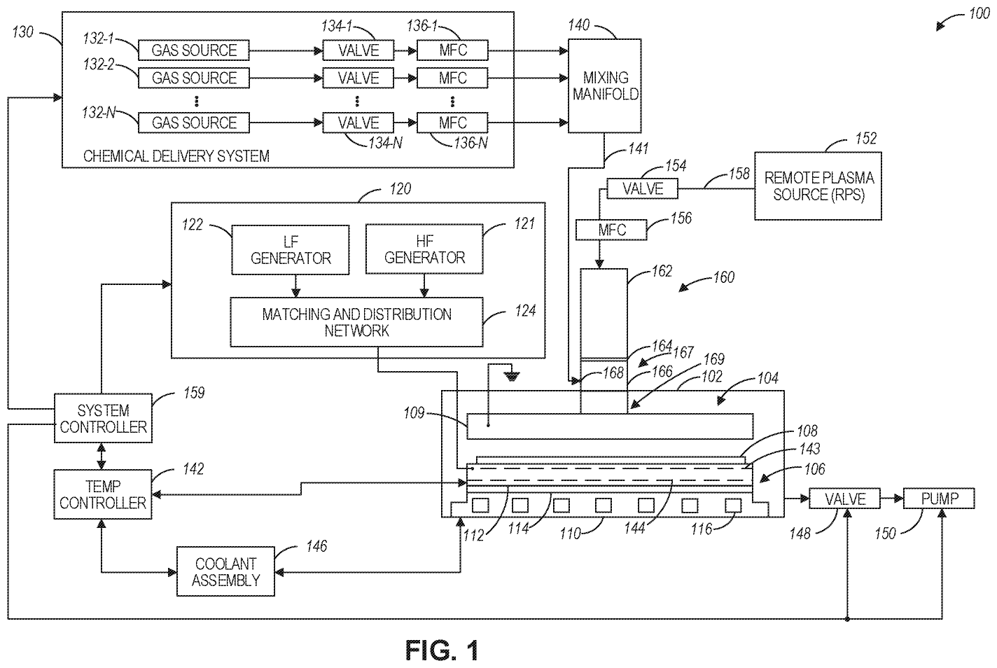

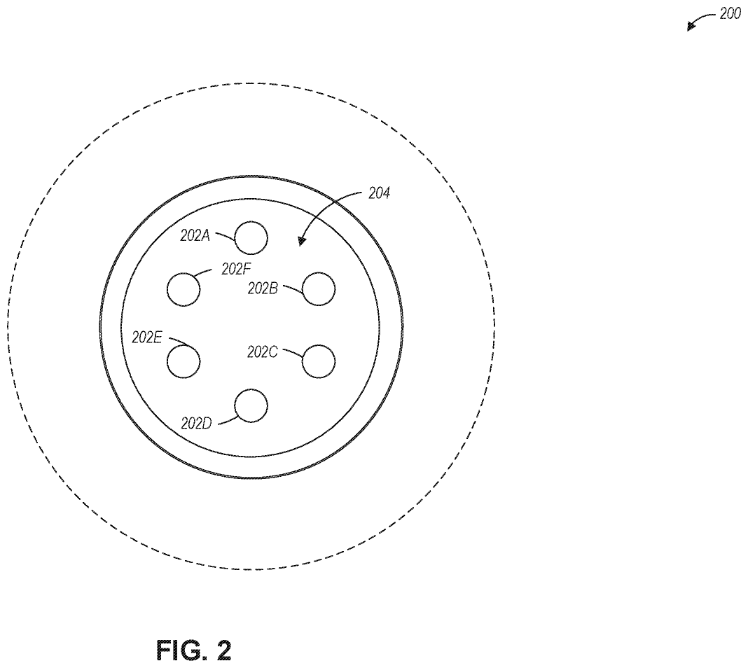

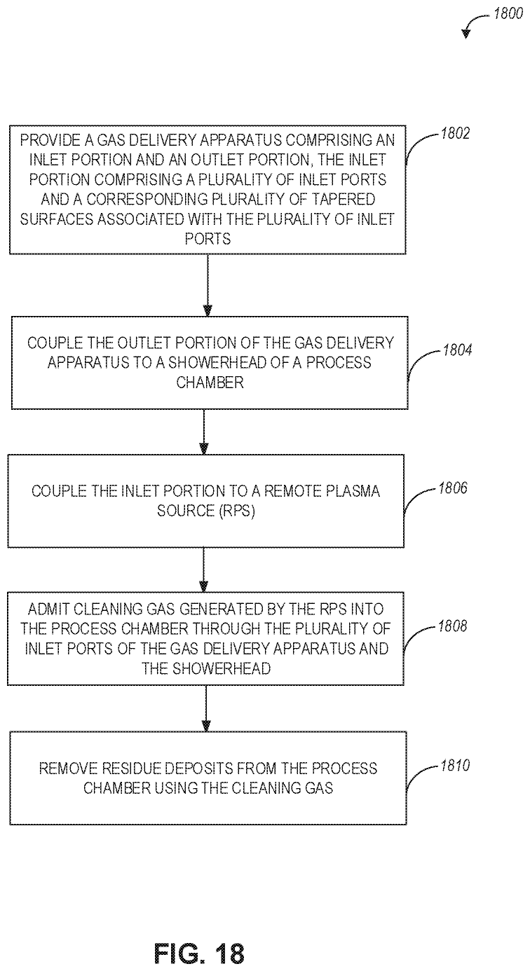

In some aspects, a tube assembly can be used to deliver the process gasses into the process chamber via a showerhead. The tube assembly can also be used to deliver cleaning gas and purge gas for in-situ cleaning of the process chamber. As used herein, the terms “tube assembly” and “RPC tube” are used interchangeably. As used herein, the terms “RPC delivery inlet adapter,” “delivery inlet adapter,” “profiled end piece,” and “gas delivery apparatus” are used interchangeably. A more detailed description of a substrate processing apparatus with a process chamber and an RPC tube is provided in connection with FIG. 1. FIGS. 2-17 illustrate different configurations of an inlet portion of a delivery inlet adapter of the RPC tube. FIG. 18 is a flowchart of a method for removing residue deposits from a process chamber using a delivery inlet adapter with profiled surfaces.

In some aspects, the delivery inlet adapter of an RPC tube can include an inlet portion with a flat surface. The flat surface lies perpendicularly to the clean gas flow path. An example of such an inlet portion is illustrated in FIG. 2. In the event of particle excursions from the chamber, particles can accumulate on this horizontal surface. The result of such accumulation can be an unacceptable number of adders on a substrate after a deposition or cleaning process is run. The adders on the wafer can be arranged in a pattern consistent with the orientation and spacing of the inlet ports on the RPC delivery inlet adapter. In this regard, flat surfaces of existing geometries can create a stagnation zone—assisted by gravity—so any particles that find their way onto the top of the non-swept existing design can accumulate there. The disclosed techniques use a tapered surface design associated with a slope that is not favored for accumulation by gravity and is also not a gas flow stagnation location (streamlines of gas are much less likely to recirculate).

In some embodiments, the delivery inlet adapter of an RPC tube can comprise an inlet portion with a tapered surface around each inlet port. In this regard, the inlet portion includes no flat surfaces, resulting in reduced accumulation of adders. In some aspects, the delivery inlet adapter can be configured based on eliminating continuous horizontal surfaces in the cleaning gas flow path. The delivery inlet adapter can also be configured based on using a constant elevation at the RPC tube inner diameter and holding a constant elevation at each inlet port diameter. In some aspects, surfaces of the delivery inlet adapter are configured as tangent to one another, and any discontinuities in the surfaces may be smoothed and blended using a ball-end mill type tool and/or manual finishing with an abrasive sheet (e.g., sandpaper)

The tapered surface of the delivery inlet adapter reduces the likelihood of particles accumulating on the surface. As gas flows through the RPC tube, it no longer stagnates on the surface of the delivery inlet adapter causing particle accumulation. Instead, since every part of the surface of the inlet portion of the delivery inlet adapter slopes towards an inlet port, gasses flowing through the delivery inlet adapter can remove particles from this surface in a controlled fashion. Removing the particles from the sloped surfaces can reduce the number of adders on a wafer in the event of a particle excursion from the delivery inlet adapter and onto a substrate in the process chamber.

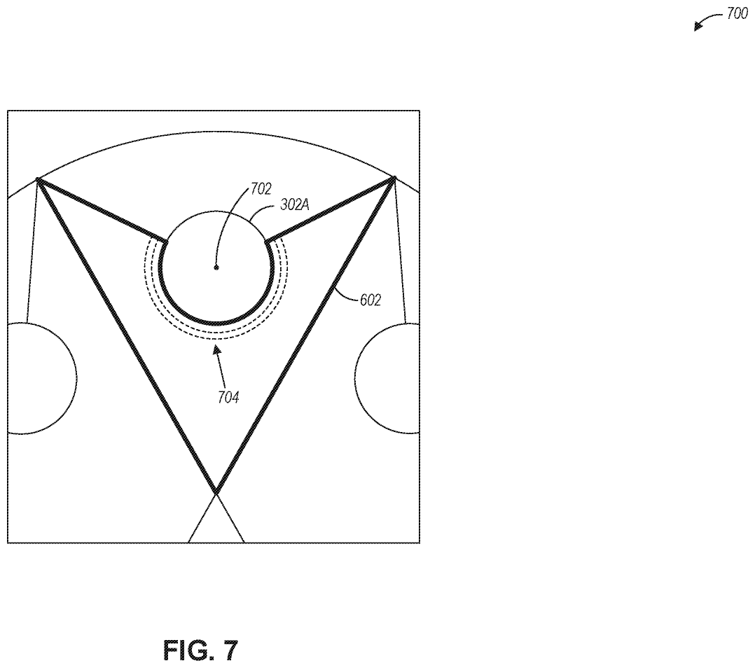

The disclosed inlet portion of the delivery inlet adapter parameterizes the space around each inlet port. The inlet portion can be manufactured by removing material from a metal or ceramic rod based on a location from the center of the RPC tube, the location from the inlet port and the distance from the RPC tube's inner wall. In some aspects, the inlet portion can be configured to include a first region and a second region, which are associated with different slopes. The first region can be disposed between the inlet port and the center of the RPC tube. The surface of the first region can be manufactured from a metal or ceramic rod by removing material using a theoretical conical tool. The conical tool can be centered on the inlet port and is associated with a constant slope, elevation, and diameter. Example configurations of the first region are illustrated in FIG. 7-FIG. 11.

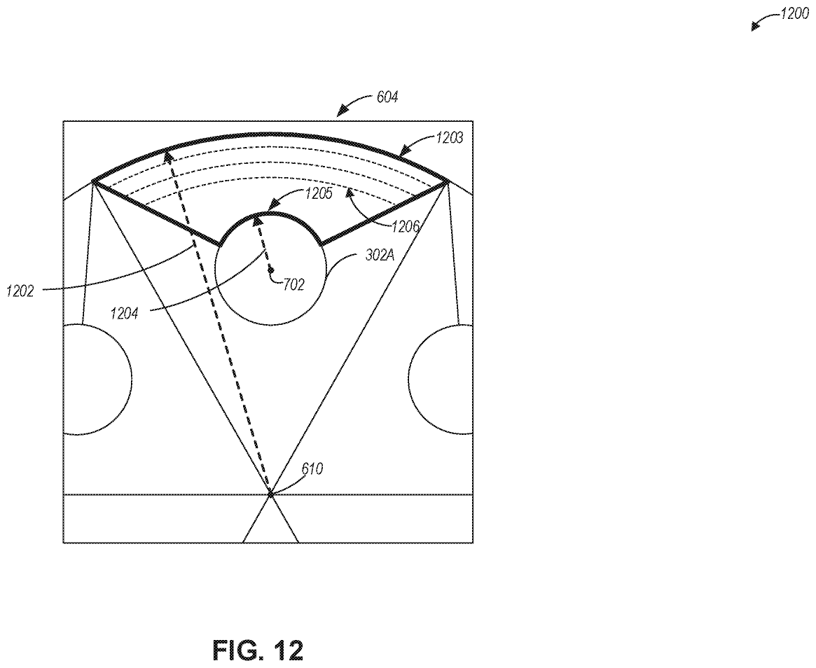

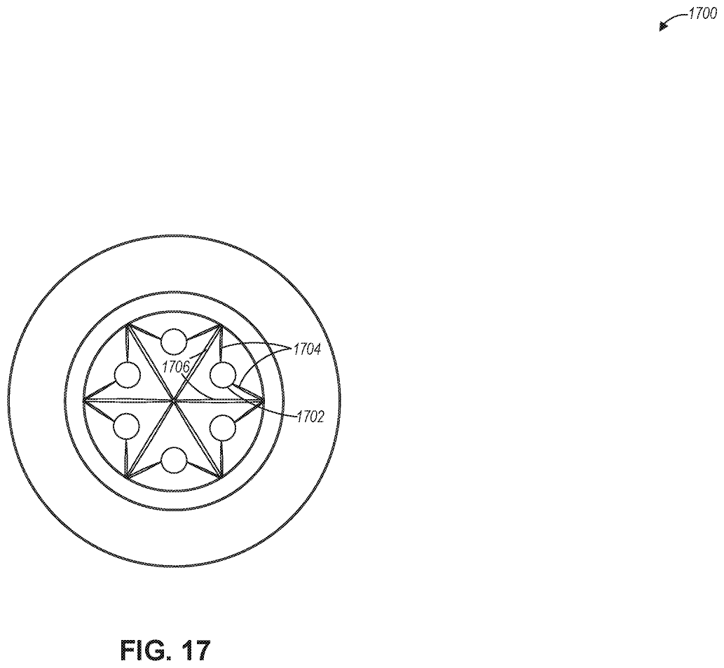

The second region can be disposed between the inlet port and the RPC tube inner diameter. The surface of the second region can be manufactured by removing material with an infinitesimally thin cylinder. At each step of removal, the cylinder changes its elevation, origin, and diameter to linearly interpolate between the RPC tube inner wall and the inlet port wall. This creates a smooth surface in the second region, with constant elevation at both the RPC tube inner diameter and the inlet port. Example configurations of the second region are illustrated in FIG. 12-FIG. 16. The first and second regions can be blended using a ball-end mill-type tool, removing the discontinuity between the surfaces. An example of blending between the regions is illustrated in FIG. 17.

The disclosed techniques are associated with removing the horizontal surface on the inlet portion of an RPC delivery inlet adapter. The removal of the horizontal surface reduces the amount of RPC gas stagnation on the surface of the inlet portion, which minimizes the likelihood of particle accumulation. Additionally, the resulting surfaces of the inlet portion can be machined using a computer numerical control (CNC) milling machine (e.g., a 5-axis CNC milling machine). For example, the inlet portion can be machined by mathematically quantifying the surfaces as a function of angle, RPC tube inner diameter, and inlet port distance from the RPC tube center. This maximizes options for the manufacturability of the delivery inlet adapter while minimizing the costs of the new feature. While a similar surface can be created using blend features, the parameterization of each region can provide a smooth, repeatable surface that is quantifiable.

FIG. 1 is a functional block diagram of an example of a substrate processing system 100 in which examples of the present disclosure may be used. Referring now to FIG. 1, the example substrate processing system 100 is configured for performing deposition as shown. While a PECVD substrate processing system is shown as system 100, a PEALD substrate processing system or other substrate processing system (e.g., a processing system without using plasma for deposition or etching) may be used in connection with the cleaning techniques discussed herein. The substrate processing system 100 includes a process chamber 102 that encloses other components of the substrate processing system 100 and contains plasma. The process chamber 102 includes a gas distribution device 104 and substrate support 106, such as an electrostatic chuck (ESC). During operation, substrate 108 is arranged on the substrate support 106. In some embodiments, the substrate support can include one or more pedestals.

In some examples, the gas distribution device 104 may include a showerhead 109 that distributes process gases over substrate 108 and serves as an electrode to apply an RF field that induces ion bombardment. The showerhead 109 may include a stem portion, including one end connected to a top surface of the process chamber 102. A base portion is generally cylindrical and extends radially outwardly from an opposite end of the stem portion at a location that can be spaced from the top surface of the process chamber 102. A substrate-facing surface or faceplate of the base portion of the showerhead 109 includes a plurality of distributed holes through which process gas (or gases) flows. The gas distribution device 104 max be made of a metallic material and may act as an upper electrode. Alternately, the gas distribution device 104 may be made of a non-metallic material and may include an embedded electrode. In other examples, the upper electrode may include a conducting plate, and the process gases may be introduced in another manner.

The substrate support 106 includes a conductive baseplate 110 that acts as a lower electrode. The baseplate 110 supports a heating plate 112, which may correspond to a ceramic multi-zone heating plate. A thermal resistance layer 114 may be arranged between the heating plate 112 and the baseplate 110. Baseplate 110 may include one or more coolant channels 116 for flowing coolant through baseplate 110.

A Radio Frequency (RF) generating system 120 generates and outputs an RF voltage to one of the upper electrodes (e.g., the gas distribution device 104) and the lower electrode (e.g., the baseplate 110 of the substrate support 106). The other one of the upper electrode and the lower electrode may be direct current (DC) grounded at ground terminal 143, alternating current (AC) grounded, or floating. In some examples, the RE generating system 120 may supply dual-frequency power, including a high frequency (HF) generator 121 and a low frequency (LF) generator 122 that generate the HF and LF power (at predetermined frequencies and power levels, respectively) that is fed by a matching and distribution network 124 to the upper electrode or the lower electrode (or the showerhead).

A chemical delivery system 130 (also referred to as a chemical delivery module) includes process gas sources (such as one or more precursor canisters) 132-1, 132-2, . . . , 132-N (collectively, process gas sources 132), where N is an integer greater than zero. The process gas sources are fluidly coupled (e.g., via a plurality of gas lines) to corresponding valves 134-1, . . . , and 134-N.

The process gas sources 132 supply one or more process gas mixtures, dopants, carrier gases, liquid precursors, precursor gases, cleaning gases, and/or purge gases. In some examples, the chemical delivery system 130 delivers a precursor gas, such as a mixture of tetraethyl orthosilicate (TEOS) gas, a gas including an oxygen species and argon (Ar) gas during deposition, and dopants including triethyl phosphate (TEPO) and/or triethyl borate (TEB). In some examples, diffusion of the dopants occurs from the gas phase. For example, a carrier gas (e.g., nitrogen, argon, or other) is enriched with the desired dopant (also in gaseous form, e.g., TEPO and/or TEB) and supplied to the silicon wafer on which a concentration balance can take place. In subsequent processes, a wafer may be placed in a quartz tube that is heated to a specific temperature.

Returning to FIG. 1, the process gas sources 132 are connected by valves 134-1, . . . , and 134-N (collectively, valves 134) and mass flow controllers (MFCs) 136-1, . . . , and 136-N (collectively, MFCs 136) to a mixing manifold 140. The mixing manifold 140 is in fluid communication with process chamber 102. In some applications, there may be one or more valves between the mixing manifold 140 and the inlet port 168. The process gases are supplied to the mixing manifold 140 and mixed therein. An output of the mixing manifold 140 is fed to process chamber 102 via a process gas supply line 141 and RPC tube 160. In some aspects, the mixing manifold is heated to a predetermined temperature to supply the precursor gases to the process chamber at a specific temperature (or a temperature range).

The RPC tube 160 can comprise tubing 162, a reducing adapter 164, and a delivery inlet adapter 166. The delivery inlet adapter 166 comprises an inlet portion 167 coupled to the reducing adapter 164. The delivery inlet adapter 166 also comprises an outlet portion 169 coupled to the showerhead 109. In some embodiments, the output of the mixing manifold 140 is fed to the showerhead 109 via the supply line 141 and inlet port 168. In some embodiments, the substrate processing system 100 comprises a remote plasma source (RPS) 152 configured to generate plasma and radicals from cleaning gas and purge gas. In some aspects, RPS 152 is supplied by process gas sources 132 or other process gas sources. The cleaning gas and the purge gas can be supplied to showerhead 109 for performing in-situ cleaning of processing chamber 102. More specifically, the cleaning gas and the purge gas are supplied to showerhead 109 via supply line 158, valve 154, MFC 156, and RPC tube 160. In some embodiments, valve 154 and/or MC 156 may not be present. In some aspects, the RPS 152 can be part of the chemical delivery system 130. A more detailed description of aspects of the delivery inlet adapter 166 is provided herein below in connection with FIGS. 2-18.

A temperature controller 142 may be connected to a plurality of thermal control elements (TCEs) 144 arranged in the heating plate 112. For example, the TCEs 144 may include, but are not limited to, respective macro TCEs corresponding to each zone in a multi-zone heating plate and/or an array of micro TCEs disposed across multiple zones of a multi-zone heating plate. The temperature controller 142 may be used to control the plurality of TCEs 144 to control the temperature of the substrate support 106 and the substrate 108. Even though FIG. 1 illustrates the TCEs in the substrate support structure, the disclosure is not limited in this regard, and the TCEs can be configured in other areas of the chamber (e.g., the chamber walls). Such TCEs configured in the chamber walls could control the chamber wall temperature, which could suppress deposition and assist with the chamber cleaning techniques discussed herein (e.g., by increasing the reactivity of clean gasses arriving at wall surfaces).

The temperature controller 142 may communicate with a coolant assembly 146 to control coolant flow through channels 116. For example, the coolant assembly 146 may include a coolant pump and reservoir. The temperature controller 142 operates the coolant assembly 146 to selectively flow the coolant through channels 116 to cool the substrate support 106. A valve 148 (e.g., a gate valve) and a pump 150 (e.g., an exhaust pump) may be used to control pressure and to evacuate reactants from the processing chamber 102. In an example embodiment, the process chamber may include more than one gate valve (or other types of valves) for evacuating reactants (e.g., process gasses or cleaning gasses) and purging gasses from the chamber.

A system controller 159 may be used to control components of the substrate processing system 100. For example, system controller 159 can be configured to control the supply of cleaning gas and purging gas via the delivery inlet adapter 166 for in-situ cleaning of process chamber 102. The system controller 159 can be configured to perform other control functionalities, such as dynamically monitoring and adjusting the surface temperature of the heating elements of gas lines within the chemical delivery system 130. The system controller 159 can also be configured to perform pressure control functions, such as monitoring and adjusting the pressure within the process chamber 102. Although shown as separate controllers, temperature controller 142 may be implemented within the system controller 159.

FIG. 2 illustrates an inlet portion of a first gas delivery apparatus such as an RPC tube, which can be used in connection with removing residue deposits from a process chamber. Referring to FIG. 2, the inlet portion 200 can include inlet ports 202A, 202B, 202C, 202D, 202E, and 202F disposed on a flat surface 204. The flat surface 204, which can be oriented horizontally with respect to gravity, lies perpendicularly to the flow path of cleaning gas supplied via the delivery inlet adapter to the process chamber 102. In the event of particle excursions from the chamber, particles can accumulate on the horizontal surface 204. The accumulation of particles can lead to an unacceptable number of adders on a substrate being processed in the process chamber. The disclosed techniques may be used to configure the profiled end piece of the RPC tube with at least one sloped surface to prevent the accumulation of particles and reduce adders on the substrate.

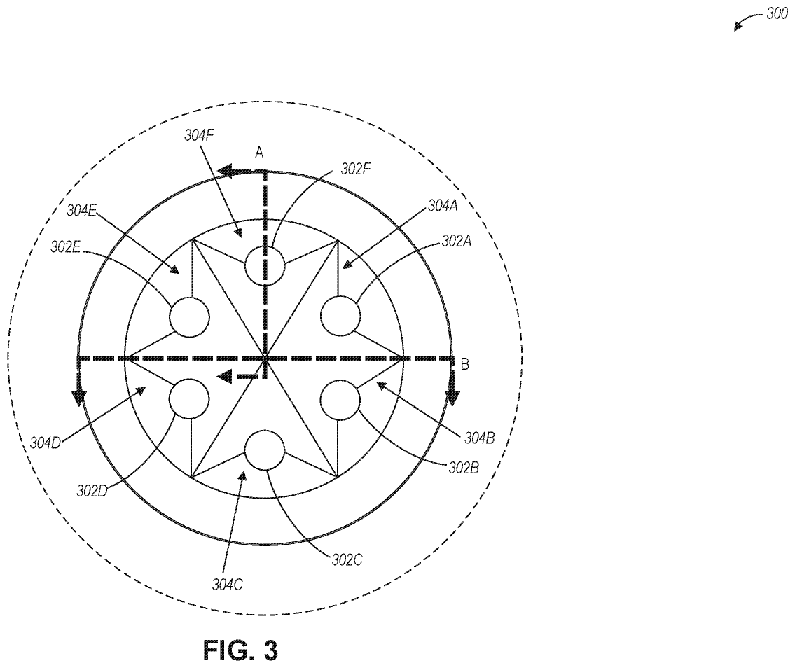

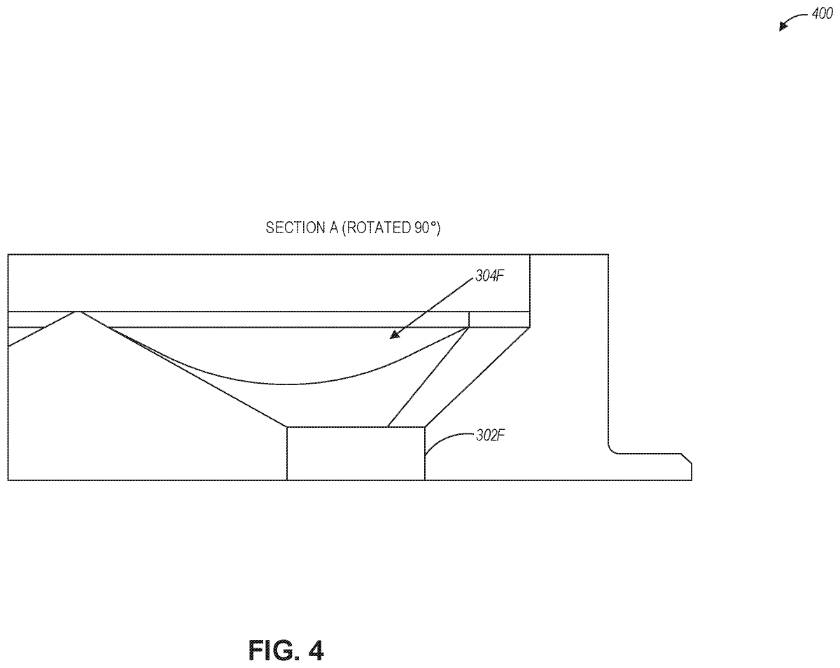

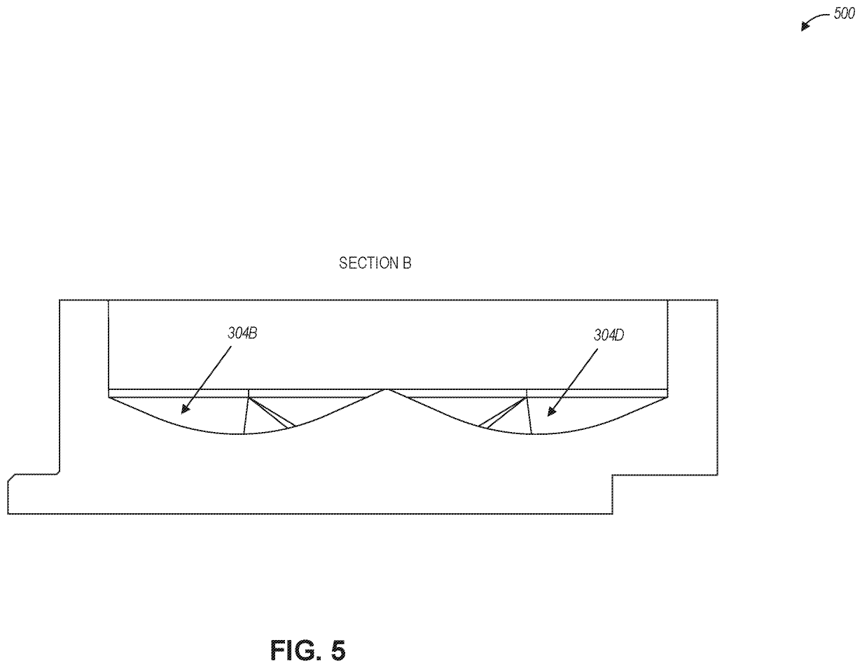

FIG. 3 illustrates a top view of an inlet portion 300 of a second gas delivery apparatus (e.g., delivery inlet adapter 166), according to example embodiments. The inlet portion 300 can comprise a plurality of tapered surfaces 304A, 304B, 304C, 304D, 304E, and 304F. The plurality of tapered surfaces 304A, 304B, 304C, 304D, 304E, and 304F can be configured to surround a corresponding plurality of inlet ports 302A, 302B, 302C, 302D 302E, and 302F. Corresponding cross-sectional views A and B of the inlet portion 300 are illustrated in FIG. 4 and FIG. 5 respectively. Even though the inlet portion 300 is illustrated with six inlet ports 302A-302F, the disclosure is not limited in this regard. More specifically, the inlet portion 300 can be configured with a different number of inlet ports and corresponding tapered surfaces.

FIG. 4 illustrates a first cross-sectional view 400 of the second gas delivery apparatus of FIG. 3, according to example embodiments. Referring to FIG. 4, the first cross-sectional view 400 illustrates tapered surface 304F surrounding inlet port 302F of the inlet portion 300 of the delivery inlet adapter 166.

FIG. 5 illustrates a second cross-sectional view 500 of the second gas delivery apparatus of FIG. 3, according to example embodiments. Referring to FIG. 5, the second cross-sectional view 500 illustrates tapered surfaces 304B and 304D of the inlet portion 300 of the delivery inlet adapter 166.

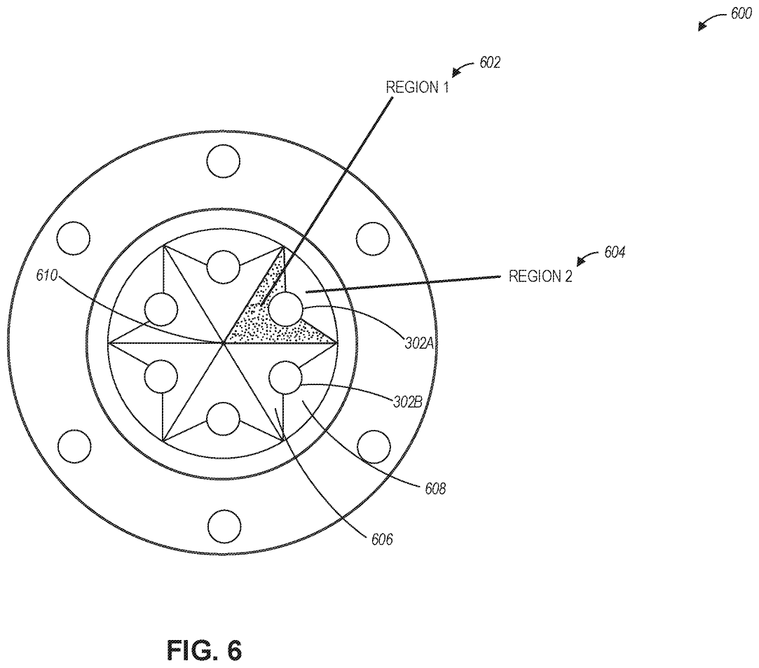

FIG. 6 illustrates a top view 600 of the inlet portion 300 of the second gas delivery apparatus of FIG. 3, including multiple sloped regions, according to example embodiments. Referring to FIG. 6, the tapered surfaces 304A-304F are disposed around a center axis 610. Each of the tapered surfaces 304A-304F can be configured with a first region and a second region. The first region can be associated with a first curvature, and the second region can be associated with a second curvature. The first curvature can be different from the second curvature. For example, tapered surface 304A surrounding inlet port 302A can comprise a first region 602 and a second region 604. Similarly, the tapered surface 304B surrounding the inlet port 302B can comprise a first region 606 and a second region 608.

In some embodiments, the first and second regions can be provided (or manufactured) using a CNC milling machine based on the disclosed configurations and characteristics for the first and second regions. For example, the CNC milling machine can be used with different milling paths (or patterns) to create the profiles associated with the first and second regions. Example milling patterns for creating the first and second regions are discussed herein below.

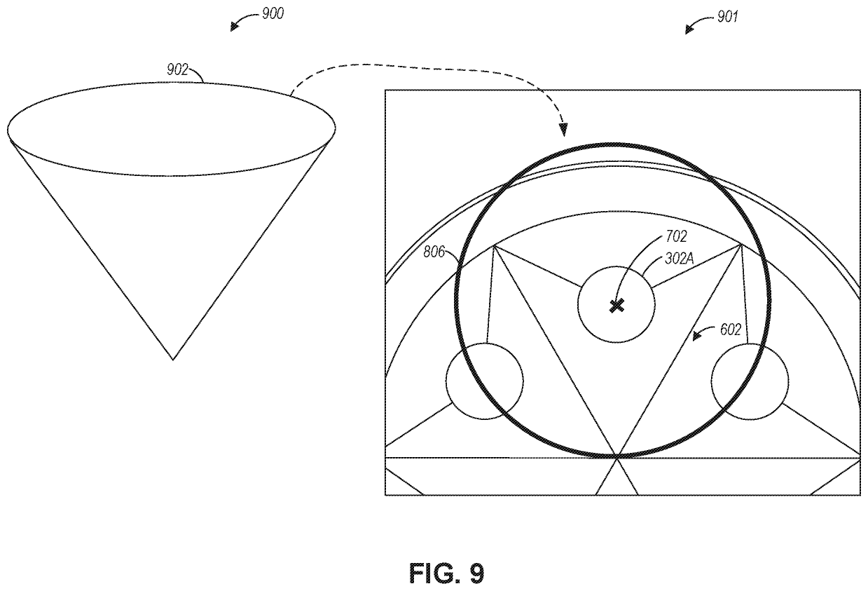

FIG. 7 illustrates a top view 700 of the first region 602 of the multiple sloped regions of FIG. 6, according to example embodiments. In some embodiments, the first region 602 is created around a center axis 702 of the inlet port 302A using a CNC milling machine (e.g., possibly equipped with a ball end mill to facilitate cutting of the tapered profile). For example, the first region 602 can be created by milling in a pattern of concentric circles 704 around the center axis 702. In this regard, the first region 602 can be associated with a cutout equivalent to using a conical tool (e.g., conical tool 902 in FIG. 9) centered at the center axis 702.

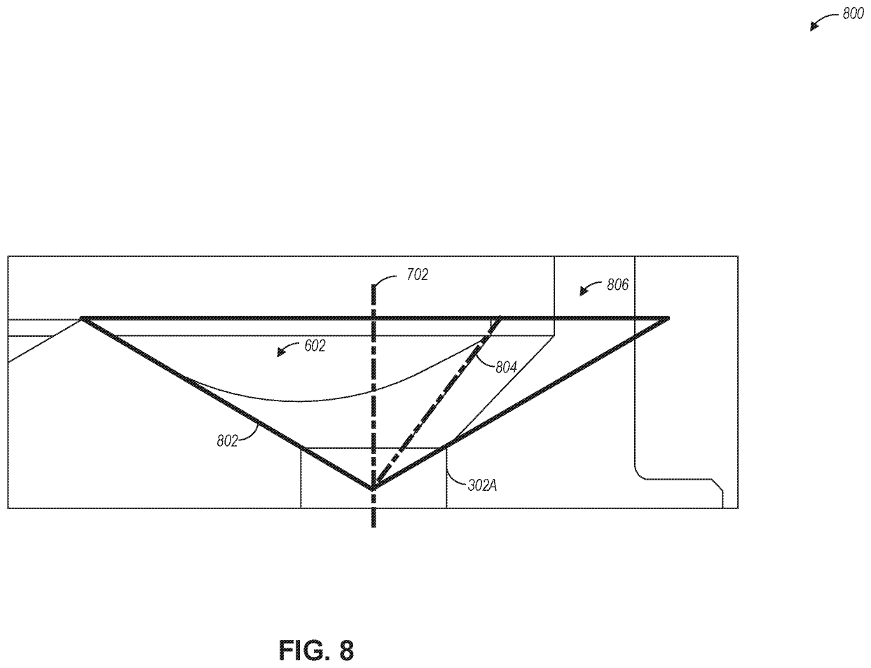

FIG. 8 illustrates a side view 800 of an example tool cutout for providing the first region 602, according to example embodiments. Referring to FIG. 8, the first region 602 can be created using a portion of a conical cutout 806 equivalent to using a conical tool (e.g., conical tool 902 in FIG. 9) centered at the center axis 702. For example, the first region 602 can be milled (e.g., from a steel rod or another type of material) so that a conical surface is achieved. The conical surface of the first region 602 can be represented by a portion of the conical cutout 806 bound by edges 802 and 804, as illustrated in FIG. 8.

FIG. 9 illustrates a perspective view 900 of the conical tool 902 and a top view 901 of the conical cutout 806 for providing the first region 602, according to example embodiments. While the first region 602 is of a conical shape, conical tool 902 (as depicted in FIG. 9) may prevent milling of the second region 604 into its intended shape because conical tool 902 may cut a full cone. In such aspects, CNC machining can be used to facilitate fabrication because a much smaller tool—with the same cone angle—can be rasterized back and forth in the radial, circumferential, and vertical directions without corrupting the second region 604.

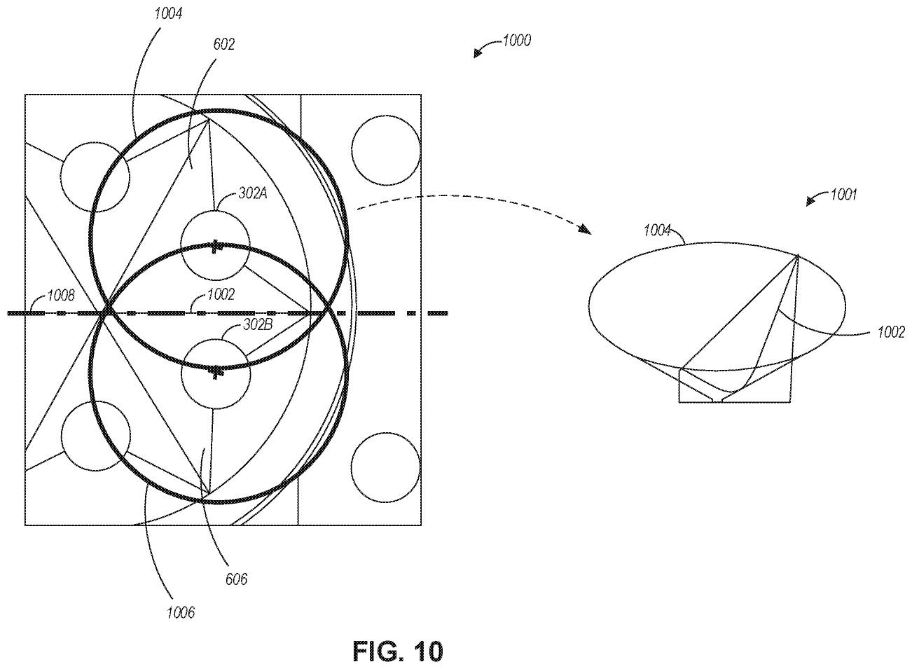

FIG. 10 illustrates a top view 1000 of multiple tool cutouts for providing neighboring first regions associated with a hyperbolic profile, according to example embodiments. Referring to FIG. 10, conical cutouts 1004 and 1006 can be used for milling first regions 602 and 606, respectively. The hyperbolas of such a profile can be noted as curved edges at the symmetry planes (e.g., along the edge of profile 1008). The hyperbolas are artifacts of cutting adjacent conical surfaces, such as regions 602 and 606.

When conical cutouts are used for creating (e.g., milling) first regions around inlet ports of the inlet portion 300, the planar interference between the conical cutouts produces hyperbolic profiles between neighboring tapered surfaces. For example, FIG. 10 illustrates a perspective view 1001 of hyperbolic profile 1002 between tapered surfaces 304A and 304B with corresponding first regions 602 and 606. FIG. 10 further illustrates a portion of a hyperbolic profile 1008 created between conical surfaces 304E and 304D.

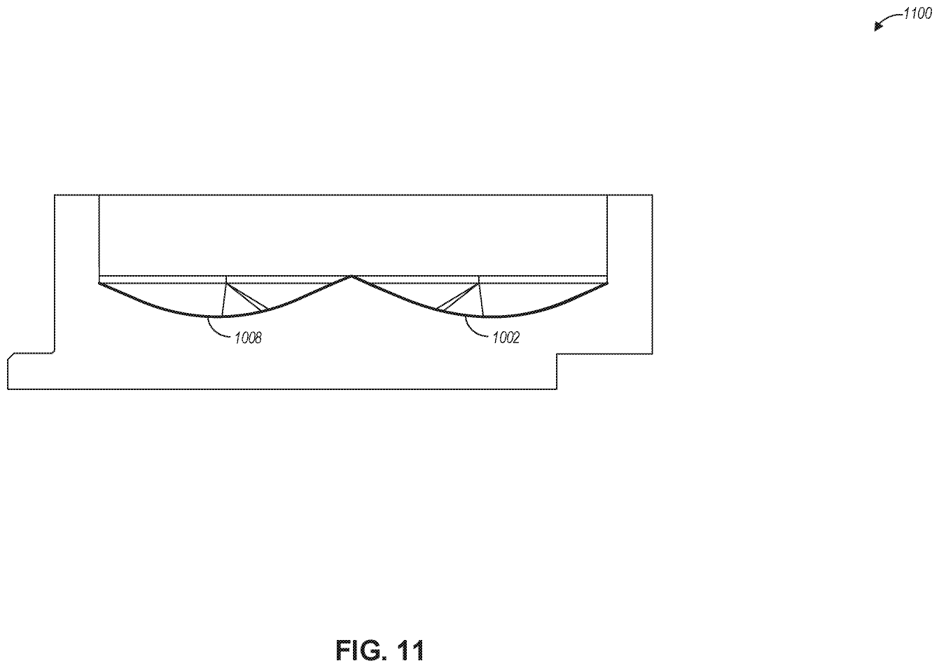

FIG. 11 illustrates a cross-sectional view 1100 of neighboring tapered surfaces associated with hyperbolic profiles, according to example embodiments. More specifically, cross-sectional view 1100 illustrates hyperbolic profiles 1002 and 1008 associated with the milling of first regions in tapered surfaces 304A, 304B, 304E, and 304D of FIG. 3.

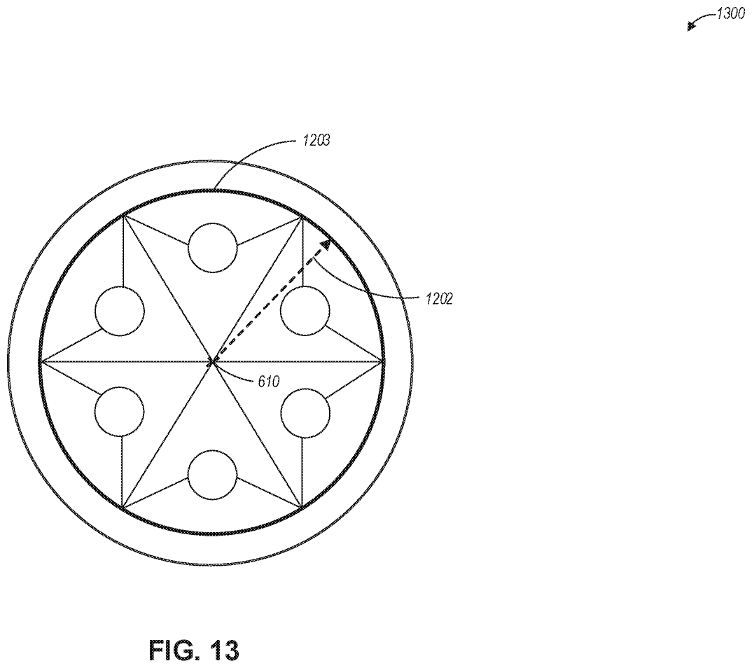

FIG. 12 illustrates a top view 1200 of the second region 604 of the multiple sloped regions (e.g., tapered surfaces 304A-304E) of FIG. 6, according to example embodiments. Referring to FIG. 12, the second region 604 can be created using a CNC milling machine (e.g., a ball end milling machine), making multiple arc-shaped cuts 1206 with differing outside diameters (ODs). For example, the milling machine can create a first (shallowest) cut 1203 following an arc with OD based on radius 1202 of the RPC tube (e.g., radius 1202 is the distance between the center axis 610 and the inner perimeter of the RPC tube 160) (e.g. the outermost tangent of the milling machine cutter can be at radius 1202 which is the inner, cylindrical wall of the RPS tube). As the depth of the cuts increases, the ODs of the cut arcs decrease, with the center axis of the cut are approaching the center axis of the corresponding inlet port. For example, a last (deepest) arc-shaped cut 1205 of the second region 604 is associated with an OD based on radius 1204 of the inlet port 302A. Different views of the first and last cuts of the second region 604 are illustrated in FIGS. 13-16.

FIG. 13 illustrates a top view 1300 of the first cut 1203, which may be used to produce the second region 604, according to example embodiments.

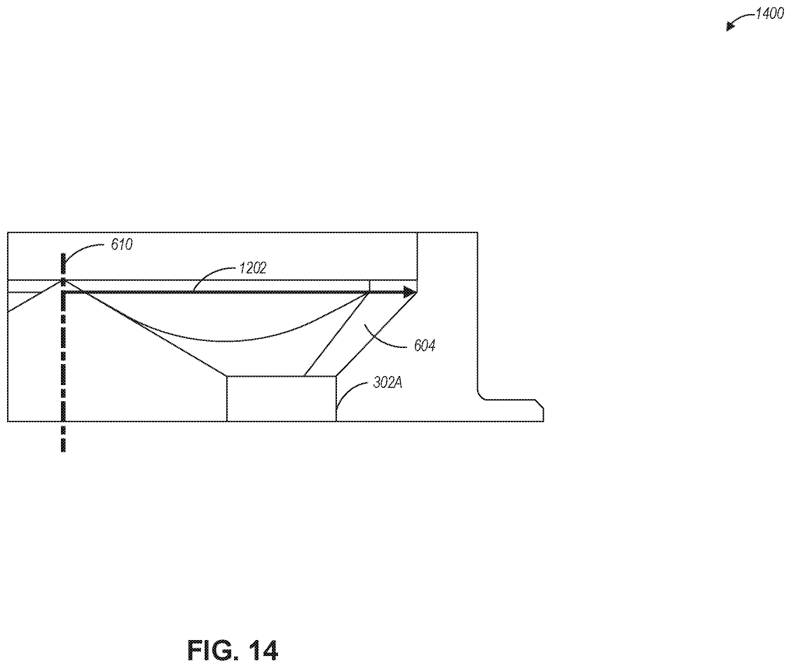

FIG. 14 illustrates a cross-sectional view 1400 of the first cut 1203 configured based on radius 1202, according to example embodiments.

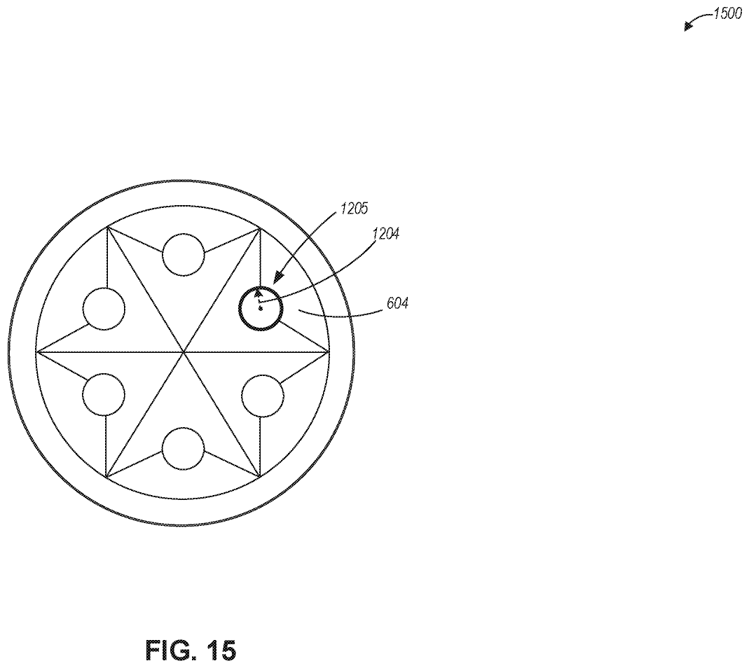

FIG. 15 illustrates atop view 1500 of the last cut 1205, which may be used to produce the second region 604, according to example embodiments.

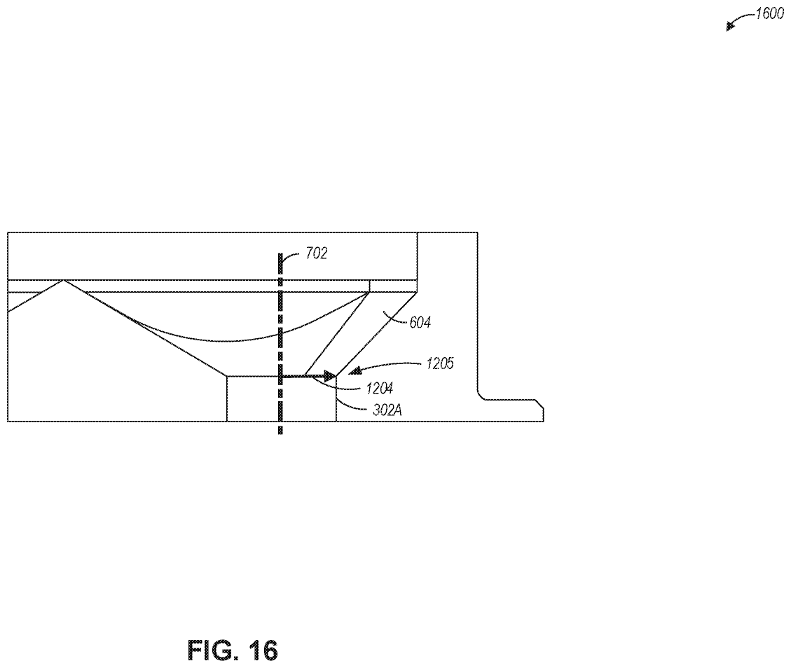

FIG. 16 illustrates a cross-sectional view 1600 of the last cut 1205 configured based on radius 1204, according to example embodiments.

FIG. 17 illustrates a top view 1700 of the inlet portion 300 of the second gas delivery apparatus of FIG. 3, including blended regions with a smooth profile between the multiple sloped regions, according to example embodiments. Referring to FIG. 17, the inlet portion 300 can be configured with example blended regions such as blended regions 1702, 1704, and 1706. In some aspects, a first blended region 1702 with a smooth profile can be configured around the opening of the inlet ports. For example, 1/16″ rounding can be added to the inlet port opening to create a blended region 1702. In some embodiments, intersections of blended regions 1704 can be blends of some non-zero radius when cutting the part with rotary milling tools. In some aspects, intersections of blended regions 1706 could have a sharper edge profile than regions 1704.

In some aspects, a second blended region 1704 can be configured between one or more edges separating a first region and a second region of a tapered surface. A third blended region 1706 can be configured between neighboring tapered surfaces. In some embodiments, blended regions 1704 and 1706 can be created by adding ⅛″ rounding to the corresponding edges between the first and second regions and between neighboring tapered surfaces. In some embodiments, different degrees of rounding may be used for blended regions 1702, 1704, and 1706.

Referring to FIGS. 1-17, a gas delivery apparatus (e.g., delivery inlet adapter 166) can comprise an inlet portion 300 (also referred to as inlet portion 167) and an outlet portion 169. The inlet portion 300 can comprise a plurality of inlet ports 302A-302F configured to receive gas from a gas source (e.g. RPS 152). The inlet portion 300 can also comprise a corresponding plurality of tapered surfaces 304A-304F associated with the plurality of inlet ports. Each tapered surface of the plurality of tapered surfaces 304A-304F surrounds a corresponding inlet port of the plurality of inlet ports 302A-302F. The outlet portion 169 can be configured to deliver the gas to gas showerhead 109 of process chamber 102.

In some embodiments, each tapered surface of the plurality of tapered surfaces 304A-304F comprises a first region and a second region. For example, tapered surface 304A comprises a first region 602 and a second region 604. The first region is associated with a first curvature, and the second region is associated with a second curvature. The first curvature can be different from the second curvature. In some aspects, the first region (e.g., the first region 602) can comprise a conical surface. The second region (e.g., the second region 604) can comprise a non-conical surface. The conical surface can be associated with a constant slope and a constant elevation. In some aspects, the conical surface can comprise a conical cutout (e.g., conical cutout 806 associated with the first region 602). The conical cutout can comprise a plurality of partial concentric circles with a common center axis (e.g., concentric circles 704 around center axis 702 of inlet port 302A).

In some embodiments, the non-conical surface can comprise a non-conical cutout (e.g., the cutout of the second region 604 created based on multiple arc-shaped cuts 1206). The non-conical cutout can comprise a plurality of arcs (e.g., multiple arc-shaped cuts 1206). The plurality of arcs can be associated with a corresponding plurality of center axes that are non-coincidental with each other (e.g., the OD of each arc changes as discussed in connection with FIG. 12).

In some embodiments, each tapered surface of the plurality of tapered surfaces can further comprise a first blended region (e.g., blended region 1704) disposed between the first region and the second region. Additionally, each tapered surface of the plurality of tapered surfaces can further comprise a second blended region (e.g., blended region 1702) disposed around the inlet port of the tapered surface.

FIG. 18 is a flowchart of method 1800 for removing residue deposits from a process chamber using a delivery inlet adapter with profiled surfaces, according to an example embodiment. Method 1800 includes operations 1802, 1804, 1806, 1808, and 1810, which may be performed by control logic (or the control logic configures or causes other modules to perform the function), such as the system controller 159 of FIG. 1. For example, the system controller 159 can be configured to manage the operation of the substrate processing system 100, including performing operations associated with in-situ cleaning to remove residue deposits from the process chamber.

At operation 1802, a gas delivery apparatus (e.g., delivery inlet adapter 166) can be provided. The gas delivery apparatus can include an inlet portion (e.g., inlet portion 167 or 300) and an outlet portion (e.g., outlet portion 169). The inlet portion can comprise a plurality of inlet ports (e.g., inlet ports 302A-302F). The inlet portion can also comprise a corresponding plurality of tapered surfaces (e.g., tapered surfaces 304A-304F) associated with the plurality of inlet ports. Each tapered surface of the plurality of tapered surfaces surrounds a corresponding inlet port of the plurality of inlet ports.

At operation 1804, the outlet portion (e.g., the outlet portion 169) of the gas delivery apparatus can be coupled to a showerhead (e.g., showerhead 109) of the process chamber.

At operation 1806, the inlet portion (e.g., inlet portion 300) can be coupled to a remote plasma source (e.g., RPS 152).

At operation 1808, cleaning gas generated by the RPS can be admitted into the process chamber through the plurality of inlet ports of the gas delivery apparatus and the showerhead. For example, cleaning gas generated by the RPS 152 can be admitted into process chamber 102 via supply line 158, valve 154, MFC 156, tubing 162, reducing adapter 164, delivery inlet adapter 166, and showerhead 109.

At operation 1810, residue deposits can be removed from the process chamber using the cleaning gas.

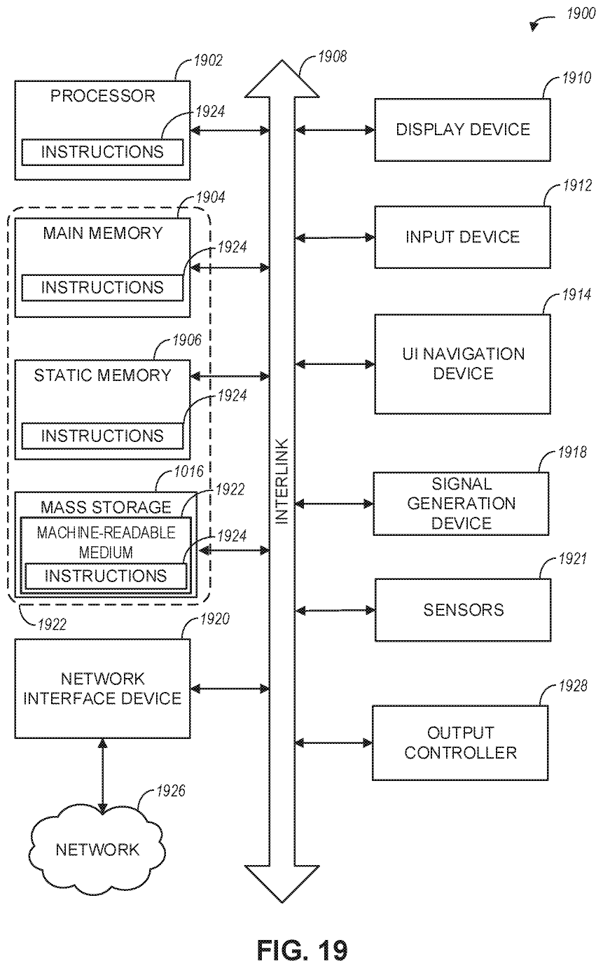

FIG. 19 is a block diagram illustrating an example of a machine 1900 upon which one or more example method embodiments may be implemented or by which one or more example embodiments may be controlled. In alternative embodiments, the machine 1900 may operate as a standalone device or may be connected (e.g., networked) to other machines. In a networked deployment, the machine 1900 may operate in the capacity of a server machine, a client machine, or both in server-client network environments. In an example, the machine 1900 may act as a peer machine in a peer-to-peer (P2P) (or other distributed) network environment. Further, while only a single machine 1900 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g. hardwired). In an example, the hardware of the circuitry may include variably connected physical components (e.g., execution units, transistors, simple circuits), including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry or by a third circuit in a second circuitry at a different time.

The machine (e.g., computer system) 1900 may include a hardware processor 1902 (e.g., a central processing unit (CPU), a hardware processor core, a graphics processing unit (GPU), or any combination thereof), a main memory 1904, and a static memory 1906, some or all of which may communicate with each other via an interlink (e.g., bus) 1908. The machine 1900 may further include a display device 1910, an alphanumeric input device 1912 (e.g., a keyboard), and a user interface (UT) navigation device 1914 (e.g., a mouse). In an example, the display device 1910, the alphanumeric input device 1912, and the UT navigation device 1914 may be a touch screen display. The machine 1900 may additionally include a mass storage device (e.g., drive unit) 1916, a signal generation device 1918 (e.g., a speaker), a network interface device 1920, and one or more sensors 1921. Machine 1900 may include an output controller 1928, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1902n may perform the functionalities of the system controller 159 or any control logic discussed hereinabove to configure and control functionalities described herein in connection with removing residue deposits from a process chamber or configuring tapered surfaces of a delivery inlet adapter of an RPC tube. In this regard, the hardware processor 1902 can be configured as a processor of a device (e.g., a milling machine or another apparatus) configured to create components (e.g., the delivery inlet adapter) of an RPC tube based on the disclosed techniques or configurations.

The mass storage device 1916 may include a machine-readable medium 1922 on which one or more sets of data structures or instructions 1924 (e.g., software) embodying or utilized by any one or more of the techniques or functions described herein can be stored. The instructions 1924 may also reside, completely or at least partially, within the main memory 1904, within the static memory 1906, or the hardware processor 1902 during execution thereof by the machine 1900. In an example, one or any combination of the hardware processor 1902, the main memory 1904, the static memory 1906, or the mass storage device 1916 may constitute machine-readable media.

While the machine-readable medium 1922 is illustrated as a single medium, the term “machine-readable medium” may include a single medium or multiple media (e.g., a centralized or distributed database and/or associated caches and servers) configured to store the one or more instructions 1924.

The term “machine-readable medium” may include any medium that is capable of storing, encoding, or carrying instructions 1924 for execution by the machine 1900 and that causes the machine 1900 to perform any one or more of the techniques of the present disclosure or that is capable of storing, encoding, or carrying data structures used by or associated with such instructions 1924. Non-limiting machine-readable medium examples may include solid-state memories and optical and magnetic media. In an example, a massed machine-readable medium comprises a machine-readable medium 1922 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1924 may further be transmitted or received over a communications network 1926 using a transmission medium via the network interface device 1920.

Implementation of the preceding techniques may be accomplished through any number of specifications, configurations, or example deployments of hardware and software. It should be understood that the functional units or capabilities described in this specification may have been referred to or labeled as components or modules to emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations, which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center) than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations, including over different storage devices, and may exist, at least partially, merely as electronic signals on a system or network. The components or modules may be passive or active, including agents operable to perform desired functions.

Described implementations of the subject matter can include one or more features, alone or in combination, as illustrated below by way of examples.

Example 1 is a gas delivery apparatus comprising an inlet portion, the inlet portion comprising a plurality of inlet ports configured to receive gas from a gas source, and a corresponding plurality of tapered surfaces associated with the plurality of inlet ports, each tapered surface of the plurality of tapered surfaces surrounding a corresponding inlet port of the plurality of inlet ports; and an outlet portion, the outlet portion configured to deliver the gas to a gas showerhead of a process chamber.

In Example 2, the subject matter of Example 1 includes subject matter where each tapered surface of the plurality of tapered surfaces comprises a first region and a second region, the first region having a first curvature, the second region having a second curvature, and the first curvature being different from the second curvature.

In Example 3, the subject matter of Example 2 includes subject matter where the first region comprises a conical surface and wherein the second region comprises a non-conical surface.

In Example 4, the subject matter of Example 3 includes subject matter where the conical surface is associated with a constant slope and a constant elevation.

In Example 5, the subject matter of Examples 3-4 includes subject matter where the conical surface comprises a conical cutout, the conical cutout comprising a plurality of partial concentric circles with a common center axis.

In Example 6, the subject matter of Examples 3-5 includes subject matter where the non-conical surface comprises a non-conical cutout, the non-conical cutout comprising a plurality of arcs, the plurality of arcs associated with a corresponding plurality of center axes that are non-coincidental with each other.

In Example 7, the subject matter of Examples 2-6 includes subject matter where each tapered surface of the plurality of tapered surfaces further comprises a first blended region disposed between the first region and the second region.

In Example 8, the subject matter of Example 7 includes subject matter where each tapered surface of the plurality of tapered surfaces further comprises a second blended region disposed around the inlet port of the tapered surface.

Example 9 is a method for removing residue deposits from a process chamber, the method comprising providing a gas delivery apparatus, the gas delivery apparatus comprising an inlet portion and an outlet portion, the inlet portion comprising a plurality of inlet ports and a corresponding plurality of tapered surfaces associated with the plurality of inlet ports, each tapered surface of the plurality of tapered surfaces surrounding a corresponding inlet port of the plurality of inlet ports; coupling the outlet portion of the gas delivery apparatus to a showerhead of the process chamber; coupling the inlet portion to a remote plasma source (RPS); admitting cleaning gas generated by the RPS into the process chamber through the plurality of inlet ports of the gas delivery apparatus and the showerhead; and removing the residue deposits from the process chamber using the cleaning gas.

In Example 10, the subject matter of Example 9 includes admitting purge gas into the process chamber through the plurality of inlet ports of the gas delivery apparatus and the showerhead, where the admitted gas can be used to remove clean byproducts.

In Example 11, the subject matter of Examples 9-10 includes subject matter where each tapered surface of the plurality of tapered surfaces comprises a first region and a second region, the first region having a first curvature, the second region having a second curvature, and the first curvature being different from the second curvature.

In Example 12, the subject matter of Example 11 includes subject matter where the first region comprises a conical surface and wherein the second region comprises a non-conical surface.

In Example 13, the subject matter of Example 12 includes subject matter where the conical surface is associated with a constant slope and a constant elevation.

Example 14 is a semiconductor substrate processing apparatus, the apparatus comprising: a remote plasma source (RPS) configured to generate plasma and radicals from a cleaning gas; a gas delivery apparatus coupled to the RPS, the gas delivery apparatus comprising an inlet portion and an outlet portion, the inlet portion comprising: a plurality of inlet ports configured to receive gas from a gas source; and a corresponding plurality of tapered surfaces associated with the plurality of inlet ports, each tapered surface of the plurality of tapered surfaces surrounding a corresponding inlet port of the plurality of inlet ports; a process chamber in which a semiconductor substrate is processed and residue deposits are formed, the process chamber fluidly coupled to the RPS via the inlet portion and the outlet portion; and a controller module coupled to the RPS, the gas delivery apparatus, and the process chamber, the controller module to cause the RPS to generate the radicals from the cleaning gas that flow into the process chamber via the inlet portion and the outlet portion.

In Example 15, the subject matter of Example 14 includes subject matter where each tapered surface of the plurality of tapered surfaces comprises a first region and a second region, the first region having a first curvature, the second region having a second curvature, and the first curvature being different from the second curvature.

In Example 16, the subject matter of Example 15 includes subject matter where the first region comprises a conical surface and wherein the second region comprises a tapered, non-conical surface.

In Example 17, the subject matter of Example 16 includes subject matter where the conical surface is associated with a constant slope and a constant elevation.

In Example 18, the subject matter of Examples 16-17 includes subject matter where the conical surface comprises a conical cutout, the conical cutout comprises a plurality of partial concentric circles with a common center axis, and the non-conical surface comprises a non-conical cutout, the non-conical cutout comprising a plurality of arcs, the plurality of arcs associated with a corresponding plurality of center axes that are non-coincidental with each other.

In Example 19, the subject matter of Examples 16-18 includes subject matter where each tapered surface of the plurality of tapered surfaces further comprises a first blended region disposed between the first region and the second region.

In Example 20, the subject matter of Example 19 includes subject matter where each tapered surface of the plurality of tapered surfaces further comprises a second blended region disposed around the inlet port of the tapered surface.

Example 21 is at least one machine-readable medium, including instructions that, when executed by processing circuitry, cause the processing circuitry to perform operations to implement any of Examples 1-20.

Example 22 is an apparatus comprising means to implement any of Examples 1-20.

Example 23 is a system to implement any of Examples 1-20.

Example 24 is a method to implement any of Examples 1-20.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in the context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

What is claimed is:

1. A gas delivery apparatus comprising:
an inlet portion, the inlet portion comprising:
a plurality of inlet ports configured to receive gas from a gas source; and
a corresponding plurality of tapered surfaces associated with the plurality of inlet ports, each tapered surface of the plurality of tapered surfaces surrounding a corresponding inlet port of the plurality of inlet ports; and
an outlet portion, the outlet portion configured to deliver the gas to a gas showerhead of a process chamber.

2. The gas delivery apparatus of claim 1, wherein each tapered surface of the plurality of tapered surfaces comprises a first region and a second region, the first region having a first curvature, the second region having a second curvature, and the first curvature being different from the second curvature.

3. The gas delivery apparatus of claim 2, wherein the first region comprises a conical surface, and wherein the second region comprises a non-conical surface.

4. The gas delivery apparatus of claim 3, wherein the conical surface is associated with a constant slope and a constant elevation.

5. The gas delivery apparatus of claim 3, wherein the conical surface comprises a conical cutout, the conical cutout comprising a plurality of partial concentric circles with a common center axis.

6. The gas delivery apparatus of claim 3, wherein the non-conical surface comprises a non-conical cutout, the non-conical cutout comprises a plurality of arcs, and the plurality of arcs are associated with a corresponding plurality of center axes that are non-coincidental with each other.

7. The gas delivery apparatus of claim 2, wherein each tapered surface of the plurality of tapered surfaces further comprises a first blended region disposed between the first region and the second region.

8. The gas delivery apparatus of claim 7, wherein each tapered surface of the plurality of tapered surfaces further comprises a second blended region disposed around the inlet port of the tapered surface.

9. A method for removing residue deposits from a process chamber, the method comprising:
providing a gas delivery apparatus, the gas delivery apparatus comprising an inlet portion and an outlet portion, the inlet portion comprising a plurality of inlet ports and a corresponding plurality of tapered surfaces associated with the plurality of inlet ports, each tapered surface of the plurality of tapered surfaces surrounding a corresponding inlet port of the plurality of inlet ports;
coupling the outlet portion of the gas delivery apparatus to a showerhead of the process chamber;
coupling the inlet portion to a remote plasma source (RPS);
admitting cleaning gas and radicals generated by the RPS into the process chamber through the plurality of inlet ports of the gas delivery apparatus and the showerhead; and
removing the residue deposits from the process chamber using the cleaning gas.

10. The method of claim 9, further comprising:
admitting purge gas into the process chamber to remove clean byproducts through the plurality of inlet ports of the gas delivery apparatus and the showerhead.

11. The method of claim 9, wherein each tapered surface of the plurality of tapered surfaces comprises a first region and a second region, the first region having a first curvature, the second region having a second curvature, and the first curvature being different from the second curvature.

12. The method of claim 11, wherein the first region comprises a conical surface, and wherein the second region comprises a non-conical surface.

13. The method of claim 12, wherein the conical surface is associated with a constant slope and a constant elevation.

14. A semiconductor substrate processing apparatus, the apparatus comprising:
a remote plasma source (RPS) configured to generate radicals from a cleaning gas;
a gas delivery apparatus coupled the RPS, the gas delivery apparatus comprising an inlet portion and an outlet portion, the inlet portion comprising:
a plurality of inlet ports configured to receive gas from a gas source; and
a corresponding plurality of tapered surfaces associated with the plurality of inlet ports, each tapered surface of the plurality of tapered surfaces surrounding a corresponding inlet port of the plurality of inlet ports;
a process chamber in which a semiconductor substrate is processed and residue deposits are formed, the process chamber fluidly coupled to the RPS via the inlet portion and the outlet portion; and
a controller module coupled to the RPS, the gas delivery apparatus, and the process chamber, the controller module to cause the RPS to generate a plasma and radicals from the cleaning gas that flow into the process chamber via the inlet portion and the outlet portion.

15. The semiconductor substrate processing apparatus of claim 14, wherein each tapered surface of the plurality of tapered surfaces comprises a first region and a second region, the first region having a first curvature, the second region having a second curvature, and the first curvature being different from the second curvature.

16. The semiconductor substrate processing apparatus of claim 15, wherein the first region comprises a conical surface, and wherein the second region comprises a tapered, non-conical surface.

17. The semiconductor substrate processing apparatus of claim 16, wherein the conical surface is associated with a constant slope and a constant elevation.

18. The semiconductor substrate processing apparatus of claim 16, wherein:
the conical surface comprises a conical cutout, the conical cutout comprising a plurality of partial concentric circles with a common center axis; and
the non-conical surface comprises a non-conical cutout, the non-conical cutout comprising a plurality of arcs, the plurality of arcs associated with a corresponding plurality of center axes that are non-coincidental with each other.

19. The semiconductor substrate processing apparatus of claim 16, wherein each tapered surface of the plurality of tapered surfaces further comprises a first blended region disposed between the first region and the second region.

20. The semiconductor substrate processing apparatus of claim 19, wherein each tapered surface of the plurality of tapered surfaces further comprises a second blended region disposed around the inlet port of the tapered surface.
